(19) United States
(12) Patent Application Publication
(10) Pub. No.: US 2026/0344147 A1
(43) Pub. Date: Oct. 29, 2026

(54) DISPLAY PANEL AND DISPLAY DEVICE

(71) Applicants: BOE MLED TECHNOLOGY CO., LTD., Beijing (CN); BOE TECHNOLOGY GROUP CO., LTD., Beijing (CN)

(72) Inventors: Linfeng Li, Beijing (CN); Yicheng Lin, Beijing (CN); Qiuhua Meng, Beijing (CN); Huanxin Yue, Beijing (CN); Zeng Liang, Beijing (CN); Qingkai Zhang, Beijing (CN); Sen Yan, Beijing (CN)

(21) Appl. No.: 18/995,823

(22) PCT Filed: Sep. 28, 2023
(86) PCT No.: PCT/CN2023/122553

§ 371 Date: Jan. 16, 2025

(51) Int. Cl. H10H 29/49

(52) U.S. Cl. CPC H10H 29/49

(57) ABSTRACT

A display panel includes: a base substrate including a first side sub-region and a display region; a first conductive layer, a second conductive layer and a third conductive layer sequentially on the base substrate, terminals in the first side sub-region; and a signal wire including a first signal sub-wire in the first conductive layer and extending in the first direction, a second signal sub-wire in the second conductive layer and extending in the second direction and a third signal sub-wire in the third conductive layer and extending in the second direction, electrically connected to each other. The second signal sub-wire is closer to the display region than an end of the third signal sub-wire connected to the terminal, and an orthographic projection of the second signal sub-wire on the base substrate is spaced apart from an orthographic projection of the terminal on the base substrate in the second direction.

### CROSS REFERENCE TO RELATED APPLICATION(S)

This application is a Section 371 National Stage Application of International Application No. PCT/CN 2023/122553, filed on Sep. 28, 2023, entitled “DISPLAY SUBSTRATE AND DISPLAY DEVICE,” the contents of which are incorporated by reference herein in their entirety.

### TECHNICAL FIELD

The present disclosure relates to a field of display technology, and in particular to a display panel and a display device.

### BACKGROUND

With a development of display technology, the public has increasingly diversified demands for size, shape and display effect of electronic display devices, and thus places more requirements for wire design of display panels. How to design a wire structure to improve a yield of display products while meeting the requirements of diversified display products is one of topics that display product developers are concerned about.

The above information disclosed in this section is just for understanding of the background of the present disclosure. Therefore, the above information may contain information that does not constitute a related art.

### SUMMARY

In an aspect, a display panel is provided, including: a base substrate, including a display region and at least one side region, where the at least one side region is closer to a side edge of the base substrate than the display region, the at least one side region includes a first side sub-region and a second side sub-region, and the first side sub-region is closer to the side edge of the base substrate than the second side sub-region; a plurality of pixel units in the display region, where the plurality of pixel units are arranged on the base substrate in an array in a first direction and a second direction intersecting with the first direction, and at least one of the plurality of pixel units includes a light emitting diode and a pixel driving circuit for driving the light emitting diode; a plurality of terminals on the base substrate and in the first side sub-region; and at least one signal wire on the base substrate, where at least part of the at least one signal wire extends from the first side sub-region to the display region through the second side sub-region, and the at least one signal wire has one end electrically connected to at least one of the plurality of terminals and the other end electrically connected to the pixel driving circuit; where the display panel further includes: a first conductive layer on the base substrate; a second conductive layer on a side of the first conductive layer away from the base substrate; and a third conductive layer on a side of the second conductive layer away from the base substrate, where the at least one signal wire includes a first signal sub-wire, a second signal sub-wire and a third signal sub-wire electrically connected to each other; the first signal sub-wire is located in the first conductive layer and extends in the first direction; the second signal sub-wire is located in the second conductive layer and extends in the second direction; the third signal sub-wire is located in the third conductive layer and extends in the second direction; at least one of an orthotropic projection of the second signal sub-wire on the base substrate and an orthographic projection of the third signal sub-wire on the base substrate overlaps an orthotropic projection of the first signal sub-wire on the base substrate; and an end of the third signal sub-wire is connected to at least one of the plurality of terminals, the orthographic projection of the second signal sub-wire on the base substrate is closer to the display region than an orthographic projection of the end of the third signal sub-wire connected to the at least one of the plurality of terminals on the base substrate, and the orthographic projection of the second signal sub-wire on the base substrate is spaced apart from an orthographic projection of the at least one of the plurality of terminals on the base substrate in the second direction.

According to some exemplary embodiments, a part of the orthographic projection of the third signal sub-wire on the base substrate falls within the first side sub-region; the end of the third signal sub-wire is connected to the at least one of the plurality of terminals, and the second signal sub-wire is electrically connected to the third signal sub-wire through the first signal sub-wire.

According to some exemplary embodiments, the second signal sub-wire is electrically connected to the first signal sub-wire through at least one first via hole.

According to some exemplary embodiments, the display panel further includes a conductive transfer portion in the second conductive layer; and the third signal sub-wire is electrically connected to one end of the conductive transfer portion through a second via hole.

According to some exemplary embodiments, the other end of the conductive transfer portion is electrically connected to the first signal sub-wire through a third via hole.

According to some exemplary embodiments, the display panel further includes m data lines and n signal wires, the plurality of terminals include m data terminals and n signal terminals, the m data lines have m ends electrically connected to the m data terminals respectively, and the n signal wires have n ends electrically connected to the n signal terminals respectively, where m and n are positive integers greater than or equal to 3; and at least one of the m data terminals is provided between any two adjacent signal terminals among the n signal terminals.

According to some exemplary embodiments, the m data lines are located in the second conductive layer; and at least one of the m data lines is provided between second signal sub-wires of any two adjacent signal wires among the n signal wires in the second conductive layer.

According to some exemplary embodiments, at least one of the plurality of terminals includes a first sub-terminal in the second conductive layer and a second sub-terminal in the third conductive layer, and the first sub-terminal is electrically connected to the second sub-terminal through a fourth via hole.

According to some exemplary embodiments, in the second conductive layer, the second signal sub-wire includes a cut-off side facing the first sub-terminal, the first sub-terminal includes a first surface facing the cut-off side, and the cut-off side is spaced apart from the first surface by a predetermined distance in the second direction.

According to some exemplary embodiments, in the second direction, the cut-off side of the second signal sub-wire is closer to the at least one of the plurality of terminals than the first signal sub-wire electrically connected to the second signal sub-wire.

According to some exemplary embodiments, in the second direction, the cut-off side of the second signal sub-wire is closer to the at least one of the plurality of terminals than each of a first via hole electrically connected to the second signal sub-wire, a second via hole electrically connected to the second signal sub-wire and a third via hole electrically connected to the second signal sub-wire.

According to some exemplary embodiments, in the second side sub-region, the orthographic projection of the third signal sub-wire on the base substrate covers an orthotropic projection of the second signal sub-wire transmitting a same signal as the third signal sub-wire on the base substrate.

According to some exemplary embodiments, in the second side sub-region, a width of the orthographic projection of the third signal sub-wire on the base substrate in the first direction is greater than a width of the orthographic projection of the second signal sub-wire transmitting the same signal as the third signal sub-wire on the base substrate in the first direction.

According to some exemplary embodiments, the n signal wires include at least two of: a first voltage signal wire configured to transmit a first voltage signal; a second voltage signal wire configured to transmit a second voltage signal; a third voltage signal wire configured to transmit a third voltage signal; an initialization signal wire configured to transmit an initialization signal; and a pulse voltage signal wire configured to transmit a pulse voltage signal.

According to some exemplary embodiments, cut-off sides of the second signal sub-wires of the n signal wires are respectively opposite to and spaced apart from first surfaces of the n signal terminals in the second direction; and n distances between the cut-off sides of the second signal sub-wires of the n signal wires and the first surfaces of the n signal terminals in the second direction are substantially equal to each other.

According to some exemplary embodiments, in the second conductive layer, a data line is provided between second signal sub-wires of any two adjacent signal wires among the n signal wires; or in the second conductive layer, two or more data lines are provided between any two adjacent second signal sub-wires; or in the second conductive layer, a data line is provided between second signal sub-wires of two adjacent signal wires among at least two of the n signal wires, and two or more data lines are provided between second signal sub-wires of two adjacent signal wires among remaining ones of the n signal wires.

According to some exemplary embodiments, the first signal sub-wires of the n signal wires include at least two of: a first signal sub-wire of a first voltage signal wire configured to transmit a first voltage signal; a first signal sub-wire of a second voltage signal wire configured to transmit a second voltage signal; a first signal sub-wire of a third voltage signal wire configured to transmit a third voltage signal; a first signal sub-wire of an initialization signal wire configured to transmit an initialization signal; and a first signal sub-wire of a pulse voltage signal wire configured to transmit a pulse voltage signal, where in the second side sub-region, the first signal sub-wires of at least two of the n signal wires are arranged at intervals in the second direction.

According to some exemplary embodiments, in the second side sub-region, the first signal sub-wire of the pulse voltage signal wire, the first signal sub-wire of the third voltage signal wire, the first signal sub-wire of the second voltage signal wire, the first signal sub-wire of the first voltage signal wire and the first signal sub-wire of the initialization signal wire are arranged at intervals and sequentially arranged away from the plurality of terminals in the second direction.

According to some exemplary embodiments, in the second side sub-region, first via holes respectively configured to electrically connect first signal sub-wires and second signal sub-wires of at least two signal wires are spaced apart from each other in the first direction and the second direction.

According to some exemplary embodiments, in the second side sub-region, second via holes respectively configured to electrically connect third signal sub-wires of at least two signal wires and conductive transfer portions are spaced apart from each other in the first direction and aligned with each other in the second direction.

According to some exemplary embodiments, in the second side sub-region, a width of the orthographic projection of the third signal sub-wire on the base substrate in the first direction is greater than a width of an orthographic projection of a second signal sub-wire transmitting a same signal as the third signal sub-wire on the base substrate in the first direction; and/or in the second side sub-region, the width of the orthographic projection of the second signal sub-wire on the base substrate in the first direction is greater than a width of an orthographic projection of a data line on the base substrate in the first direction.

In another aspect, a display device is provided, including the display panel as described above.

According to some exemplary embodiments, the display device includes a plurality of display panels spliced together.

### BRIEF DESCRIPTION OF THE DRAWINGS

With the following description of the present disclosure with reference to the accompanying drawings, other objectives and advantages of the present disclosure may be clear and the present disclosure may be understood comprehensively.

FIG. 1 shows a schematic plan view of a display panel according to some embodiments of the present disclosure;

FIG. 2 shows a schematic diagram of a pixel driving circuit of a display panel according to some embodiments of the present disclosure;

FIG. 3 shows a schematic partial plan view of a display panel according to some embodiments of the present disclosure;

FIG. 4 shows a schematic partial cross-sectional view of a display panel according to some embodiments of the present disclosure;

FIG. 5 shows a schematic partial plan view of a display panel according to some embodiments of the present disclosure;

FIG. 6A and FIG. 6B show equivalent circuit diagrams of a partial region of a display panel according to some embodiments of the present disclosure;

FIG. 7 shows a schematic partial plan view of a third conductive layer of a display panel according to some embodiments of the present disclosure;

FIG. 8 shows a schematic partial plan view of a second conductive layer of a display panel according to some embodiments of the present disclosure;

FIG. 9 shows a schematic partial plan view of a combination of a second conductive layer and a first conductive layer of a display panel according to some embodiments of the present disclosure;

FIG. 10 shows a schematic enlarged plan view of region A1 in FIG. 9, where a first via hole is shown;

FIG. 11 shows connection via holes between a third conductive layer and a second conductive layer of a display panel according to some embodiments of the present disclosure;

FIG. 12 shows a schematic partial plan view of a display panel according to some embodiments of the present disclosure;

FIG. 13A to FIG. 13C show schematic partial plan views of a display panel according to some embodiments of the present disclosure;

FIG. 14 shows a schematic structural diagram of a display device according to some embodiments of the present disclosure; and

FIG. 15 shows a schematic structural diagram of a display device according to some embodiments of the present disclosure.

### DETAILED DESCRIPTION OF EMBODIMENTS

In the following description, for the purpose of explanation, many specific details are set forth to provide comprehensive understanding of various exemplary embodiments. However, it is clear that various exemplary embodiments may be implemented without these specific details or with one or more equivalent arrangements. In other cases, well-known structures and devices are shown in block diagrams in order to avoid unnecessarily obscuring the various exemplary embodiments. In addition, the various exemplary embodiments may be different, but need not be exclusive. For example, without departing from the inventive concept, a specific shape, configuration and characteristic of an exemplary embodiment may be used or implemented in another exemplary embodiment.

In the accompanying drawings, for clarity and/or description purposes, sizes and relative sizes of elements may be enlarged. Accordingly, the size and relative size of each element need not to be limited to those shown in the accompanying drawings. When the exemplary embodiments may be implemented differently, the specific process sequence may be different from the sequence described. For example, two consecutively described processes may be performed substantially simultaneously or in a reverse order. In addition, the same reference numeral represents the same element.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe the relationship between elements, for example, “between” and “directly between”, “adjacent” and “directly adjacent”, “on” and “directly on”, and so on, should be interpreted in a similar manner. In addition, the term “connection” may refer to a physical connection, an electrical connection, a communication connection, and/or a fluid connection.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Herein, the term “transistor” may refer to a triode, a thin film transistor or a field effect transistor, or other devices having the same characteristics. In embodiments of the present disclosure, in order to distinguish two electrodes other than a control electrode of the transistor, one electrode is referred to as a first electrode and the other electrode is referred to as a second electrode. In practical operations, when the transistor is a thin film transistor or a field effect transistor, the first electrode may be a drain electrode and the second electrode may be a source electrode; or the first electrode may be a source electrode and the second electrode may be a drain electrode.

It should be understood that, although terms “first”, “second” and so on may be used herein to describe different elements, those elements should not be limited by those terms. Those terms are only used to distinguish one element from another element. For example, without departing from the scope of the exemplary embodiments, a first element may be named as a second element, and similarly, a second element may be named as a first element.

In some embodiments of the present disclosure, a display panel is provided. The display panel includes: a base substrate including a display region and at least one side region, where the at least one side region is closer to a side edge of the base substrate than the display region, the at least one side region includes a first side sub-region and a second side sub-region, and the first side sub-region is closer to the side edge of the base substrate than the second side sub-region; a plurality of pixel units provided in the display region, where the plurality of pixel units are arranged on the base substrate in an array in a first direction and a second direction intersecting with the first direction, and at least one pixel unit includes a light emitting diode and a pixel driving circuit for driving the light emitting diode; a plurality of terminals provided on the base substrate and located in the first side sub-region; and at least one signal wire provided on the base substrate, where at least part of the at least one signal wire extends from the first side sub-region to the display region through the second side sub-region, the at least one signal wire has one end electrically connected to the terminal and the other end electrically connected to the pixel driving circuit. The display panel further includes: a first conductive layer provided on the base substrate; a second conductive layer provided on a side of the first conductive layer away from the base substrate; and a third conductive layer provided on a side of the second conductive layer away from the base substrate. The at least one signal wire includes a first signal sub-wire, a second signal sub-wire and a third signal sub-wire electrically connected to each other; the first signal sub-wire is located in the first conductive layer and extends in the first direction; the second signal sub-wire is located in the second conductive layer and extends in the second direction; the third signal sub-wire is located in the third conductive layer and extends in the second direction; at least one of an orthographic projection of the second signal sub-wire on the base substrate and an orthographic projection of the third signal sub-wire on the base substrate overlaps with an orthotropic projection of the first signal sub-wire on the base substrate; and the orthographic projection of the second signal sub-wire on the base substrate is closer to the display region than an orthographic projection of an end of the third signal sub-wire connected to at least one terminal on the base substrate, and the orthographic projection of the second signal sub-wire on the base substrate is spaced apart from the orthotropic projection of the terminal on the base substrate in the second direction. Through the design of pixels at a wire outlet end, a probability of short circuit in a side segment may be reduced, and a yield of display product may be improved.

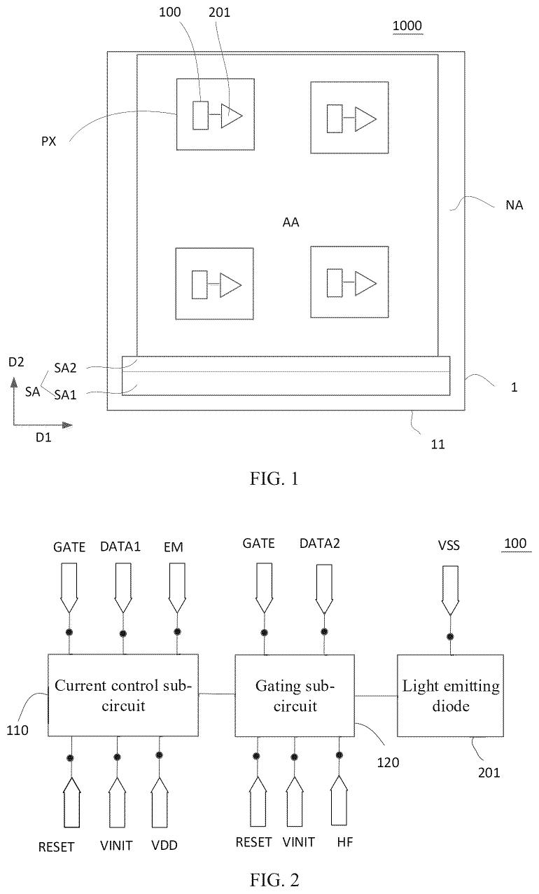

FIG. 1 shows a schematic plan view of a display panel according to some embodiments of the present disclosure.

In some embodiments of the present disclosure, referring to FIG. 1, a display panel 1000 includes: a base substrate 1, including a display region AA and a non-display region NA, where the non-display region NA includes at least one side region SA, the at least one side region SA is closer to a side edge 11 of the base substrate 1 than the display region AA, the at least one side region SA includes a first side sub-region SA1 and a second side sub-region SA2, and the first side sub-region SA1 is closer to the side edge 11 of the base substrate than the second side sub-region SA2; a plurality of pixel units PX provided in the display region, where the plurality of pixel units PX are arranged on the base substrate 1 in an array in a first direction D1 and a second direction D2 intersecting with the first direction D1, and at least one pixel unit PX includes a light emitting diode 201 and a pixel driving circuit 100 for driving the light emitting diode.

For example, each pixel PX may include a plurality of sub-pixels, such as a red sub-pixel, a green sub-pixel and a blue sub-pixel, or it may include a white sub-pixel, a red sub-pixel, a green sub-pixel and a blue sub-pixel.

In some exemplary embodiments, the light emitting diode 201 may be an inorganic light emitting diode. For example, the inorganic light emitting diode refers to a light emitting element made of an inorganic material. LED represents an inorganic light emitting element different from OLED. Specifically, an inorganic light emitting element may include mini light emitting diode (Mini LED) and micro light emitting diode (Micro LED). The micro light emitting diode (Micro LED) refers to an ultra-small light emitting diode with a grain size of less than 100 microns, and the mini light emitting diode (Mini LED) refers to a small light emitting diode with a grain size between that of Micro LED and that of an existing LED. For example, the grain size of Mini LED may range from 50 microns to 400 microns.

FIG. 2 shows a schematic diagram of a pixel driving circuit of a display panel according to some embodiments of the present disclosure.

For example, in some embodiments of the present disclosure, a pixel driving circuit 100 is provided. Referring to FIG. 2, the pixel driving circuit 100 includes a current control sub-circuit 110 and a gating sub-circuit 120.

The current control sub-circuit 110 is coupled with a scanning signal line GATE, a grayscale data line DATA1, a first voltage signal wire VDD, and an enable signal line EM. The current control sub-circuit is used to output a grayscale current signal to the light emitting diode 201 according to a grayscale data signal Datal from the grayscale data line DATA1 under the control of a scanning signal Gate of the scanning signal line GATE and an enable signal Em of the enable signal line EM.

The gating sub-circuit 120 is coupled with the scanning signal line GATE, a reset signal line RESET, a gating data line DATA2 and a pulse voltage signal wire HF. The gating sub-circuit 120 is used to drive the light emitting diode 201 to continuously emit light, under the control of the scanning signal Gate of the scanning signal line GATE and a gating data signal Data2 of the gating data line DATA2; and drive the light emitting diode 201 to intermittently emit light, under the control of a reset signal Reset of the reset signal line RESET, the gating data signal Data2 of the gating data line DATA2 and a pulse voltage signal Hf of the pulse voltage signal wire HF.

A size of the grayscale current signal is related to the first voltage signal Vdd provided by the first voltage signal wire VDD and the grayscale data signal Datal provided by the grayscale data line DATA1, and a total duration of the light emitting diode 201 intermittently emitting light is related to the pulse voltage signal Hf provided by the pulse voltage signal wire HF.

When the gating sub-circuit 120 drives the light emitting diode 201 to continuously emit light, the current control sub-circuit 110 may control a size of the grayscale data signal Data1 to achieve a control of a magnitude of a luminous intensity of the light emitting diode 201, thereby achieving a high grayscale display. When the gating sub-circuit 120 drives the light emitting diode 201 to intermittently emit light, the current control sub-circuit 110 may control the size of the grayscale data signal Datal to achieve a control of the magnitude of the luminous intensity of the light emitting diode 201, and shorten a duration of light emission of the light emitting diode 201 through the pulse voltage signal Hf, thereby achieving a low-grayscale display.

By using the pixel driving circuit 100 described above, it is possible to change a luminance of the light emitting diode 201 in a frame by controlling the size of the grayscale data signal Datal when performing a high grayscale display; and change a luminance of the light emitting diode 201 in a frame by shortening the duration of light emission of the light emitting diode 201 under a high current density when performing a low grayscale display.

Therefore, by using the pixel driving circuit 100 described above, the light emitting diode 201 may achieve a full grayscale display under a high current density, with a high luminous efficiency, a low energy consumption and a reduced cost.

In a case of a too low frequency of the pulse voltage signal, it is easy for human eyes to detect a flicker, which may affect perception. In a case of a too high frequency of the pulse voltage signal, it is difficult for hardware such as IC to implement. Based on this, in some embodiments, the frequency of the pulse voltage signal ranges from 3000 Hz to 60000 Hz, so that the flicker of the light emitting diode is not perceptible to human eyes and it is easy to implement. For example, the frequency of the pulse voltage signal Hf may be 3000 Hz, 20000 Hz, 60000 Hz, etc.

For example, for all circuits included in the display panel, the pulse voltage signals have the same frequency, and the pulse voltage signals are always maintained at a predetermined frequency or fluctuates in a small range around the predetermined frequency.

In some embodiments, the light emitting diode 201 described above is used as a light emitting unit, which may be an inorganic light emitting diode, such as Mini LED or Micro LED. The current control sub-circuit 110 may control the size of the grayscale current signal transmitted to the light emitting unit by controlling the size of the grayscale data signal Datal, thereby directly controlling the luminous intensity of the light emitting diode. The gating sub-circuit 120 may shorten an operating time length of the light emitting unit by reducing the time length of the grayscale current signal being transmitted to the light emitting unit, thereby indirectly reducing the luminous efficiency of the light emitting diode in a frame.

By adjusting parameters of signals such as data signal, first voltage signal, second voltage signal, initialization voltage signal and pulse voltage signal, it is possible to control the grayscale of the light emitting unit and improve a display effect of the display product.

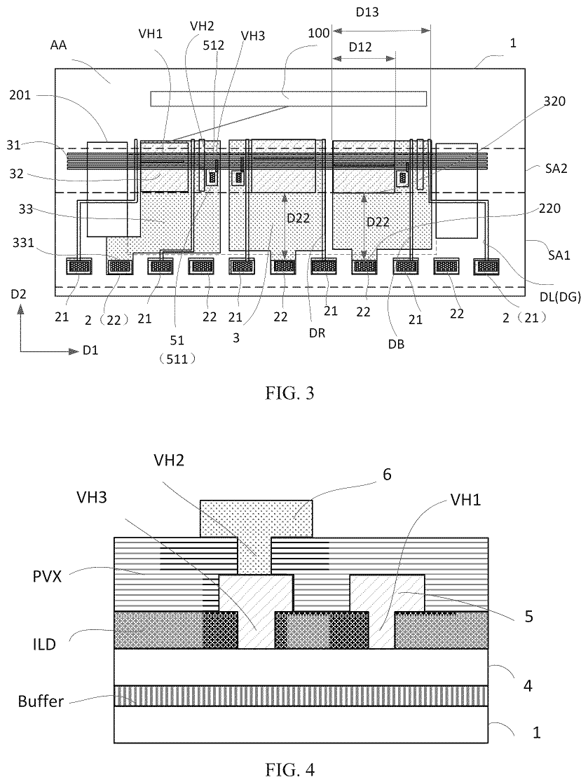

FIG. 3 shows a schematic partial plan view of a display panel according to some embodiments of the present disclosure.

In some embodiments of the present disclosure, referring to FIG. 1 and FIG. 3, the display panel includes: a plurality of terminals 2 provided on the base substrate 1 and located in the first side sub-region SA1; and at least one signal wire 3 provided on the base substrate, where at least part of the at least one signal wire 3 extends from the first side sub-region SA1 to the display region AA through the second side sub-region SA2, and the at least one signal wire 3 has one end electrically connected to the terminal 2 and the other end electrically connected to the pixel driving circuit 100, that is, at least one pixel driving circuit 100 is electrically connected to at least one terminal 2 through the at least one signal wire 3. The terminal may be electrically connected to an external driving circuit or driving chip, so that a driving signal may be written to the pixel driving circuit 100. Through the design of pixel connection wire at the wire outlet end, for example, through the design of the layout of the signal wire and the terminal, a probability of short circuit of the signal wire in the side segment such as the side region SA may be reduced, and the yield of the display product may be improved.

FIG. 4 shows a schematic partial cross-sectional view of a display panel according to some embodiments of the present disclosure.

For example, in some embodiments of the present disclosure, referring to FIG. 4, the display panel includes: a first conductive layer 4 provided on the base substrate 1; a second conductive layer 5 provided on a side of the first conductive layer 4 away from the base substrate 1; and a third conductive layer 6 provided on a side of the second conductive layer 5 away from the base substrate. An insulation layer, such as an isolation layer ILD, a passivation layer PVX and other functional layers, may be provided between adjacent conductive layers, and the insulation layer may include one layer or multiple layers. Adjacent conductive layers may be electrically connected through via holes. For example, the first conductive layer 4 may be electrically connected to the second conductive layer 5 through a first via hole VH1, and/or the first conductive layer 4 may also be electrically connected to the second conductive layer 5 through a third via hole VH3, and/or the second conductive layer 5 may be electrically connected to the third conductive layer 6 through a second via hole VH2. Through the design of multiple via holes, film layers in different conductive layers may be electrically connected, and different conductive layers may or may not be adjacent to each other.

Referring to FIG. 3 and FIG. 4, the at least one signal wire 3 includes a first signal sub-wire 31, a second signal sub-wire 32 and a third signal sub-wire 33 that are electrically connected to each other. The first signal sub-wire 31 is located in the first conductive layer 4 and extends in the first direction D1. The second signal sub-wire 32 is located in the second conductive layer 5 and extends in the second direction D2. The third signal sub-wire 33 is located in the third conductive layer 6 and extends in the second direction D2. At least one of an orthographic projection of the second signal sub-wire 32 on the base substrate 1 and an orthographic projection of the third signal sub-wires 33 on the base substrate 1 overlaps at least partially with an orthotropic projection of the first signal sub-wire 31 on the base substrate. The orthographic projection of the second signal sub-wire 32 on the base substrate does not fall within the first side sub-region SA1. The orthographic projection of the second signal sub-wire 32 on the base substrate 1 is spaced apart from an orthotropic projection of the terminal 2 on the base substrate 1 in the second direction D2.

Continuing to refer to FIG. 3, a part of the orthographic projection of the third signal sub-wire 33 on the base substrate 1 falls within the first side sub-region SA1, and an end 331 of the third signal sub-wire 33 is connected to at least one terminal 2. The second signal sub-wire 32 is electrically connected to the third signal sub-wire 33 through the first signal sub-wire 31. The terminal 2 may be electrically connected to an external driving circuit or driving chip, so that a signal may be sequentially written into the third signal sub-wire 33, the first signal sub-wire 31 and the second signal sub-wire 32 through the terminal 2, and further written into the pixel driving circuit 100, thereby achieving a control of the pixel unit.

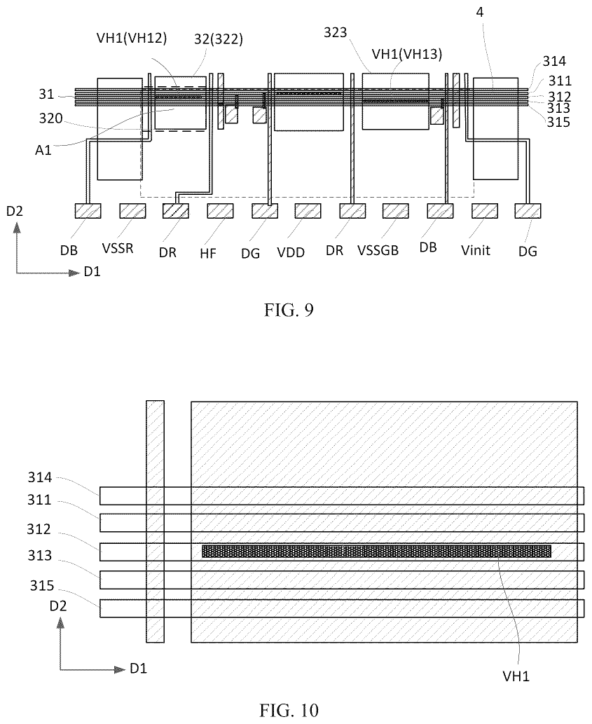

For example, referring to FIG. 3 and FIG. 9, the second signal sub-wire 32 is electrically connected to the first signal sub-wire 31 through at least one first via hole VH1.

For example, in some embodiments of the present disclosure, referring to FIG. 3 and FIG. 4, the display panel further includes a conductive transfer portion 51 in the second conductive layer 5, and the third signal sub-wire 33 is electrically connected to an end 511 of the conductive transfer portion 51 through the second via hole VH2.

For example, the other end 512 of the conductive transfer portion 51 is electrically connected to the first signal sub-wire 31 through a third via hole VH3.

The first signal sub-wire 31, the second signal sub-wire 32 and the third signal sub-wire 33 located in different conductive layers are electrically connected through the first via hole VH1, the second via hole VH2, the third via hole VH3 and the conductive transfer portion 51, so that the second signal sub-wire may be electrically connected to the terminal 2 through the first signal sub-wire and the third signal sub-wire without passing through the first side sub-region SA1. Moreover, the terminal 2 may be electrically connected to an external driving circuit or driving chip, so that a signal may be written into the second signal sub-wire 32 through the terminal 2.

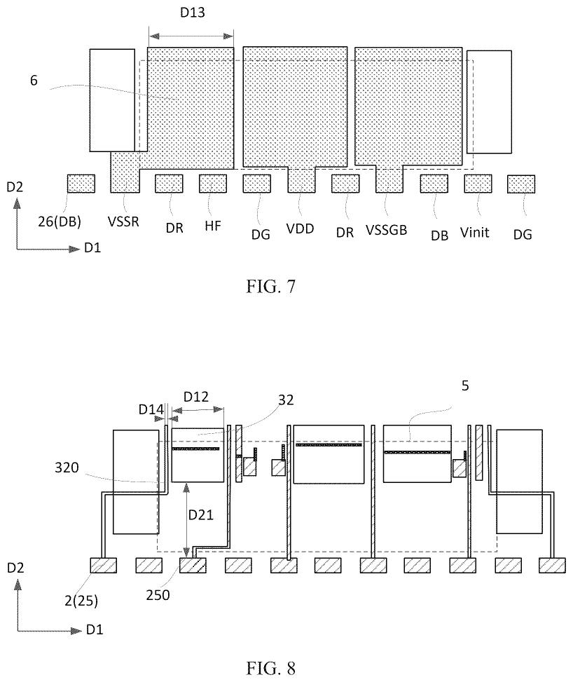

Referring to FIG. 3, FIG. 7 and FIG. 8, the orthographic projection of the second signal sub-wire 32 on the base substrate is closer to the display region AA than the orthographic projection of one end of the third signal sub-wire 33 connected to at least one terminal 2 on the base substrate. Specifically, the second signal sub-wire 32 includes a cut-off side 320 facing the terminal 2, and the third signal sub-wire 33 extends directly to the terminal 2 for a direct electrical contact with the terminal 2. That is to say, the cut-off side 320 of the second signal sub-wire 32 facing the terminal 2 is spaced apart from the terminal 2 or the end of the third signal sub-wire 33 in contact with the terminal 2 by a distance, so that the cut-off side 320 of the second signal sub-wire 32 facing the terminal 2 is indented towards the display region AA relative to the end of the third signal sub-wire 33 in contact with the terminal 2, that is, the second signal sub-wire 32 is indented relative to the third signal sub-wire 33.

Through the indentation of the second signal sub-wire 32, an in-plane via hole connection design is adopted to replace an existing design of two metal wires being led to the terminal together, so that the number of signal wires of the wire outlet end at the edge may be reduced, the probability of wire damage at the wire outlet end in the subsequent processing such as back etching is reduced, the probability of short circuit in the side segment is reduced, and the yield of the display product is improved.

For example, continuing to refer to FIG. 3, the display panel may further include at least one data line DL used to transmit a data signal, and the at least one data line DL may be used to write a data signal required to drive the light emitting unit. For example, the data line DL may include a data line DB used to write a data signal for driving the blue light emitting unit; and/or the data line DL may include a data line DR used to write a data signal for driving the red light emitting unit; and/or the data line DL may include a data line DG used to write a data signal for driving the green light emitting unit. The data lines DL used to drive light emitting units having different colors may be led out through the second side sub-region SA2 and the first side sub-region SA1 and electrically connected to the terminal 2. Moreover, the terminal may be electrically connected to an external driving circuit or driving chip, so that the signal may be written into the data line DL through the terminal 2.

It should be noted that the same or different numbers of data lines may be provided to drive light emitting units having different colors, which is not limited in embodiments of the present disclosure.

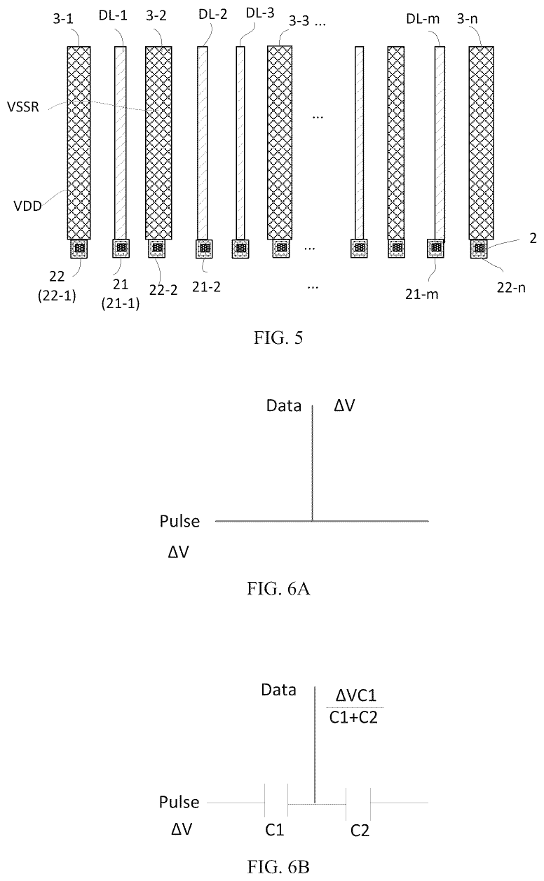

FIG. 5 shows a schematic partial plan view of a display panel according to some embodiments of the present disclosure.

For example, in some embodiments of the present disclosure, referring to FIG. 5, the display panel may include m data lines DL, such as data line DL-1, data line DL-2, data line DL-3 . . . data line DL-m. The display panel may further include n signal wires 3, such as signal wire 3-1, signal wire 3-2, signal wire 3-3 . . . signal wire 3-n. The plurality of terminals 2 include m data terminals 21 and n signal terminals 22, the m data lines DL have m ends electrically connected to the m data terminals 21 respectively, and the n signal wires 3 have n ends electrically connected to the n signal terminals 22 respectively, where m and n are positive integers greater than or equal to 3.

For example, at least one data terminal 21 is provided between any two adjacent signal terminals 22. For example, referring to FIG. 5, a data terminal 21-1 is provided between a signal terminal 22-1 and a signal terminal 22-2.

By separating common signal wires (with mesh pattern) using data lines, if a defect such as short circuit exists in a product when detecting the product subsequently, a defective region may be accurately positioned and may be repaired in a targeted manner. For example, referring to FIG. 5, if a short circuit occurs in a flying probe process, as the common signal wires such as the first voltage signal wire VDD, the second voltage signal wire VSSR in the full-plane signal wires are separated by data lines, two short circuit signals may be accurately determined in flying probe detection data. For example, taking the data line DL-1 and the signal wire 3-2 as examples, the signal wire 3-2 may be a second voltage signal wire VSSR used to provide a second voltage signal. If the data on the data line DL-1 and the data on the signal wire 3-2 are abnormal, specific positions of the two signals may be accurately determined in the plane, and a repair may be performed in the specific positions in a targeted manner, so as to avoid further laser etching of other wires that have been etched which will cause an over-etching of these wires, thereby improving a repair efficiency and improving an overall process yield.

FIG. 6A and FIG. 6B show equivalent circuit diagrams of a partial region of a display panel according to some embodiments of the present disclosure.

For example, in some embodiments of the present disclosure, the signal wire provides a direct current signal, and the signal wire and the data line are arranged alternately. An energized signal wire may not only provide a signal for the display panel, but also act as a capacitor in the energized circuit to stabilize the data signal in the data line and reduce a coupling crosstalk between the data signal Data and pulses Pulse of other signals. Referring to FIG. 6A and FIG. 6B, when no signal wire is provided on either side of the data line to provide a direct current signal, the equivalent circuit diagram is as shown in FIG. 6A. If a pulse change of other signals is ΔV, a change in the data signal Data is also ΔV as the data signal is susceptible to coupling crosstalk from other signals in an adjacent design. If the data signal and the signal wire are arranged alternately, the equivalent circuit diagram is as shown in FIG. 6B. If each side of the data signal Data in the data line is provided with a direct current signal, the direct current signals on both sides may be regarded as capacitors C1 and C2. When the pulse change of other signals is ΔV, due to the existence of the direct current signals C1 and C2, the change in the data signal Data depends on the size of C1 and C2 and may be C1/(C1+C2)⋅ΔV, so that the data signal Data may be stabilized, and the coupling crosstalk between the data signal Data and other signals may be reduced.

FIG. 7 shows a schematic partial plan view of a third conductive layer of a display panel according to some embodiments of the present disclosure. FIG. 8 shows a schematic partial plan view of a second conductive layer of a display panel according to some embodiments of the present disclosure. FIG. 9 shows a schematic partial plan view of a combination of a second conductive layer and a first conductive layer of a display panel according to some embodiments of the present disclosure. FIG. 10 shows a schematic enlarged plan view of region A1 in FIG. 9, where a first via hole is shown. FIG. 11 shows connection via holes between a third conductive layer and a second conductive layer of a display panel according to some embodiments of the present disclosure.

In some embodiments of the present disclosure, referring to FIG. 3, FIG. 5 and FIG. 8, the m data lines DL are located in the second conductive layer 5. In the second conductive layer 5, at least one data line DL is provided between any two adjacent second signal sub-wires 32.

Referring to FIG. 7, FIG. 8 and FIG. 11, at least one terminal 2 includes a first sub-terminal 25 in the second conductive layer and a second sub-terminal 26 in the third conductive layer, and the first sub-terminal 25 is electrically connected to the second sub-terminal 26 through a fourth via hole VH4.

For example, referring to FIG. 8, in the second conductive layer 5, the second signal sub-wire 32 includes a cut-off side 320 facing the first sub-terminal 25, the first sub-terminal 25 includes a first surface 250 facing the cut-off side 320, and the cut-off side 320 is spaced apart from the first surface 250 by a predetermined distance D21 in the second direction D2.

For example, referring to FIG. 8 and FIG. 9, in the second direction D2, the cut-off side 320 of the second signal sub-wire 32 is closer to the terminal 2 than the first signal sub-wire 31 electrically connected to the second signal sub-wire 32.

For example, referring to FIG. 3 and FIG. 9, in the second direction D2, the cut-off side 320 of the second signal sub-wire 32 is closer to the terminal 2 than each of the first via hole VH1 electrically connected to the second signal sub-wire 32, the second via hole VH2 electrically connected to the second signal sub-wire 32, and the third via hole VH3 electrically connected to the second signal sub-wire 32.

Through the indentation design of the second signal sub-wire, an in-plane via hole connection design is adopted to replace an existing design of two metal wires being led to the terminal together, so that the number of wires of the wire outlet end at the edge may be reduced, the probability of wire damage at the wire outlet end in the subsequent processing such as back etching is reduced, the probability of short circuit in the side segment is reduced, and the yield of the display product is improved.

For example, in some embodiments of the present disclosure, referring to FIG. 3, in the second side sub-region SA2, the orthographic projection of the third signal sub-wire 33 on the base substrate covers the orthographic projection of the second signal sub-wire 32 transmitting the same signal as the third signal sub-wire 33 on the base substrate.

For example, referring to FIG. 3, FIG. 7 and FIG. 8, in the second side sub-region SA2, a width D13 of the orthographic projection of the third signal sub-wire 33 on the base substrate in the first direction D1 is greater than a width D12 of the orthographic projection of the second signal sub-wire 32 transmitting the same signal as the third signal sub-wire 33 on the base substrate in the first direction.

Through the design that the width D13 of the third signal sub-wire is greater than the width D12 of the second signal sub-wire transmitting the same signal as the third signal sub-wire and the orthographic projection of the third signal sub-wire on the base substrate covers the orthographic projection of the second signal sub-wire transmitting the same signal as the third signal sub-wire on the base substrate, it is possible to facilitate the in-plane wire layout, reduce the probability of short circuit in the in-plane processing, and improve the yield of the display product.

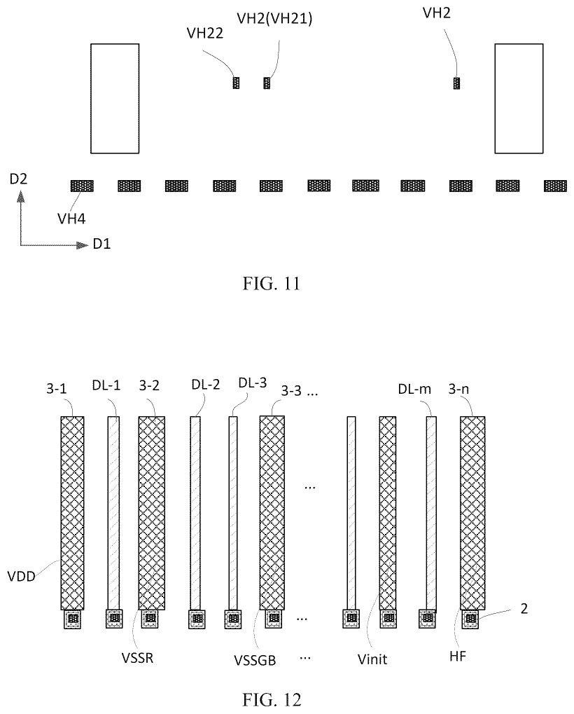

FIG. 12 shows a schematic partial plan view of a display panel according to some embodiments of the present disclosure.

For example, in some embodiments of the present disclosure, referring to FIG. 12, the n signal wires include at least two of: a first voltage signal wire VDD used to transmit a first voltage signal, a second voltage signal wire VSSR used to transmit a second voltage signal, a third voltage signal wire VSSGB used to transmit a third voltage signal, an initialization signal wire Vinit used to transmit an initialization signal, and a pulse voltage signal wire HF used to transmit a pulse voltage signal. For example, the second voltage signal wire VSSR may provide the second voltage signal to the driving circuit of the red light emitting unit, the third voltage signal wire VSSGB may provide the third voltage signal to the driving circuit of the green light emitting unit or the driving circuit of the blue light emitting unit, the first voltage signal wire VDD may provide the first voltage signal to the driving circuit of the light emitting unit, the initialization signal wire Vinit may provide the initialization signal to the driving circuit of the light emitting unit, and the pulse voltage signal wire HF may provide the pulse voltage signal to the driving circuit of the light emitting unit. For example, the light emitting unit may be one of the red light emitting unit, the green light emitting unit or the blue light emitting unit. By adjusting the first voltage signal provided by the first voltage signal wire VDD or the pulse voltage signal provided by the pulse voltage signal wire HF, it is possible to control the luminance of the light emitting unit, so as to control the grayscale of the display product and improve the display effect of the display product.

For example, in some embodiments of the present disclosure, referring to FIG. 3 and FIG. 5, the cut-off sides 320 of the second signal sub-wires 32 of the n signal wires are respectively opposite to and spaced apart from the first surfaces 220 of the n signal terminals 22 in the second direction D2. N distances D22 between the cut-off sides 320 of the second signal sub-wires 32 of the n signal wires and the first surfaces 220 of the n signal terminals 22 in the second direction D2 are substantially equal to each other.

Through the indentation design of the second signal sub-wire 32, an in-plane via hole connection design is adopted to replace an existing design of two metal wires being led to the terminal together, so that the number of signal wires of the wire outlet end at the edge may be reduced, the probability of wire damage at the wire outlet end in the subsequent processing such as back etching is reduced, the probability of short circuit in the side segment is reduced, and the yield of the display product is improved.

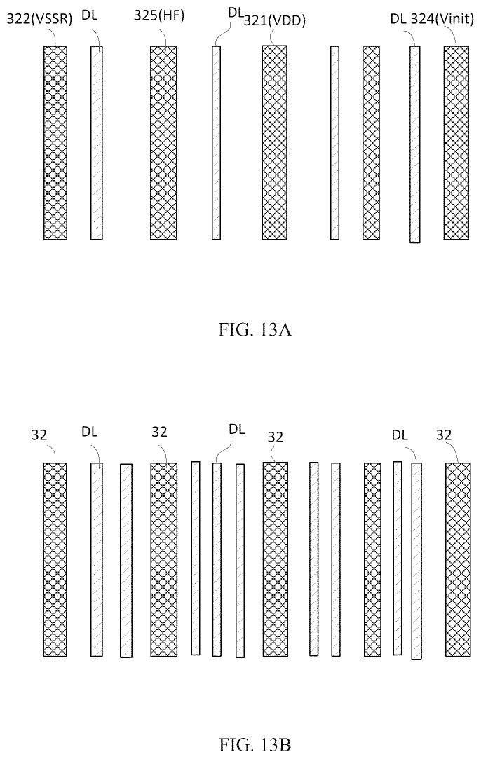

FIG. 13A to FIG. 13C show schematic partial plan views of a display panel according to some embodiments of the present disclosure.

For example, in some embodiments of the present disclosure, one or more data lines may be provided between adjacent second signal sub-wires. For example, referring to FIG. 13A to FIG. 13C, in the second conductive layer, a data line is provided between any two adjacent second signal sub-wires; alternatively, in the second conductive layer, two or more data lines are provided between any two adjacent second signal sub-wires; alternatively, in the second conductive layer, a data line is provided between two adjacent second signal sub-wires among some second signal sub-wires, and two or more data lines are provided between two adjacent second signal sub-wires among some other second signal sub-wires. The number of data lines provided between the second signal sub-wires is not specifically limited in the present disclosure.

For example, in some embodiments of the present disclosure, referring to FIG. 13A, two adjacent second signal sub-wires 32 may be at least two of: a second signal sub-wire 321 of the first voltage signal wire VDD used to transmit the first voltage signal, a second signal sub-wire 322 of the second voltage signal wire VSSR used to transmit the second voltage signal, a second signal sub-wire 323 of the third voltage signal wire VSSGB used to transmit the third voltage signal, a second signal sub-wire 324 of the initialization signal wire Vinit used to transmit the initialization signal, and a second signal sub-wire 325 of the pulse voltage signal wire HF used to transmit the pulse voltage signal.

For example, adjacent second signal sub-wires may include the second signal sub-wire 321 of the first voltage signal wire VDD used to transmit the first voltage signal and the second signal sub-wire 322 of the second voltage signal wire VSSR used to transmit the second voltage signal; and/or adjacent second signal sub-wires may include the second signal sub-wire 321 of the first voltage signal wire VDD used to transmit the first voltage signal and the second signal sub-wire 323 of the third voltage signal wire VSSGB used to transmit the third voltage signal; and/or adjacent second signal sub-wires may include the second signal sub-wire 321 of the first voltage signal wire VDD used to transmit the first voltage signal and the second signal sub-wire 324 of the initialization signal wire Vinit used to transmit the initialization signal; and/or adjacent second signal sub-wires may include the second signal sub-wire 321 of the first voltage signal wire VDD used to transmit the first voltage signal and the second signal sub-wire 325 of the pulse voltage signal wire HF used to transmit the pulse voltage signal.

It should be noted that the signals transmitted by adjacent signal wires may be determined according to actual desires, which is not limited in the present disclosure.

By separating common signal wires (with mesh pattern) using data lines, if a defect such as short circuit exists in a product when detecting the product subsequently, a defective region may be accurately positioned and may be repaired in a targeted manner. For example, if a short circuit occurs in a flying probe process, two short circuit signals may be accurately determined in flying probe detection data as the common signal wires such as the first voltage signal wire VDD and the second voltage signal wire VSSR in the full-plane signal wires are separated by data lines. It is possible to perform a repair in the specific positions in a targeted manner, so as to avoid further laser etching of other wire that have been etched which will cause an over-etching of these wires, thereby improving a repair efficiency and improving an overall process yield. Moreover, the signal wire provides a direct current signal, and the signal wire and the data line are arranged alternately. An energized signal wire may not only provide a signal for the display panel, but also act as a capacitor in the energized circuit to stabilize the data signal in the data line and reduce a coupling crosstalk between the data signal Data and pulses of other signals.

For example, in some embodiments of the present disclosure, the first signal sub-wires of a plurality of signal wires may extend in the first direction D1 and may be arranged at intervals in the second direction D2. Referring to FIG. 3 and FIG. 9, the first signal sub-wires of the n signal wires include at least two of: a first signal sub-wire 311 of the first voltage signal wire used to transmit the first voltage signal, a first signal sub-wire 312 of the second voltage signal wire used to transmit the second voltage signal, a first signal sub-wire 313 of the third voltage signal wire used to transmit the third voltage signal, a first signal sub-wire 314 of the initialization signal wire used to transmit the initialization signal, and the first signal sub-wire 315 of the pulse voltage signal wire used to transmit the pulse voltage signal. In the second side sub-region SA2, the first signal sub-wires 31 of at least two signal wires are arranged at intervals in the second direction D2.

For example, in some embodiments of the present disclosure, continuing to refer to FIG. 3 and FIG. 9, in the second side sub-region SA2, the first signal sub-wire 315 of the pulse voltage signal wire, the first signal sub-wire 313 of the third voltage signal wire, the first signal sub-wire 312 of the second voltage signal wire, the first signal sub-wire 311 of the first voltage signal wire, and the first signal sub-wire 314 of the initialization signal wire are arranged at intervals and sequentially arranged away from the plurality of terminals 2 in the second direction D2.

By providing the first signal sub-wire of the signal wire, the second signal sub-wire of the signal wire and the third signal sub-wire of the signal wire located in different regions may be electrically connected in plane, so that the number of wires of the wire outlet end at the edge may be reduced, the probability of wire damage at the wire outlet end may be reduced in the subsequent processing such as back etching, the probability of short circuit in the side segment may be reduced, and the yield of the display product may be improved.

For example, in some embodiments of the present disclosure, referring to FIG. 3 and FIG. 9, in the second side sub-region SA2, first via holes VH1 respectively used to electrically connect first signal sub-wires 31 and second signal sub-wires 32 of at least two signal wires are arranged at intervals in the first direction and the second direction. For example, a first via hole VH12 used to electrically connect the first signal sub-wire 312 and the second signal sub-wire 322 of the second voltage signal wire VSSR is spaced apart from a first via hole VH13 used to electrically connect the first signal sub-wire 313 and the second signal sub-wire 323 of the third voltage signal wire VSSGB in the first direction D1 and the second direction D2.

For example, in some embodiments of the present disclosure, referring to FIG. 3, FIG. 9 and FIG. 11, in the second side sub-region SA2, second via holes VH2 respectively used to electrically connect third signal sub-wires 33 of at least two signal wires and the conductive transfer portions 51 are spaced apart from each other in the first direction and aligned with each other in the second direction. For example, a second via hole VH 21 used to electrically connect the third signal sub-wire of the first voltage signal wire VDD and the conductive transfer portion and a second via hole VH22 used to electrically connect the third signal sub-wire of the second voltage signal wire VSSR and the conductive transfer portion are spaced apart each other in the first direction D1 and aligned with each other in the second direction D2.

For example, in some embodiments of the present disclosure, referring to FIG. 3, FIG. 7 and FIG. 8, in the second side sub-region SA2, the width D13 of the orthographic projection of the third signal sub-wire 33 on the base substrate in the first direction is greater than the width D12 of the orthographic projection of the second signal sub-wire used to transmit the same signal as the third signal sub-wire on the base substrate in the first direction; and/or in the second side sub-region, the width D12 of the orthographic projection of the second signal sub-wire on the base substrate in the first direction is greater than a width D14 of an orthographic projection of the data line on the base substrate in the first direction.

Through the design that the width D13 of the third signal sub-wire is greater than the width D12 of the second signal sub-wire used to transmit the same signal as the third signal sub-wire and the orthographic projection of the third signal sub-wire on the base substrate covers the orthographic projection of the second signal sub-wire used to transmit the same signal as the third signal sub-wire on the base substrate, it is possible to facilitate the in-plane wire layout, reduce the probability of short circuit in the in-plane processing, and improve the yield of the display product.

By setting the width of the orthographic projection of the second signal sub-wire 32 of the signal wire on the base substrate and the width of the orthographic projection of the third signal sub-wire 33 of the signal wire on the base substrate to be greater than the width of the orthographic projection of the data line on the base substrate, it is possible to improve a shielding effect of the signal wire, and the signal wire may act as a capacitor in the energized circuit to stabilize the data signal in the data line and reduce the coupling crosstalk between the data signal Data and the pulses of other signals.

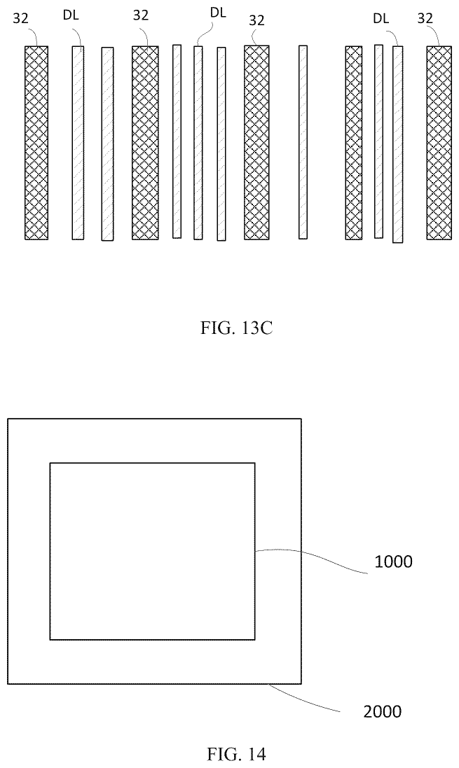

FIG. 14 shows a schematic structural diagram of a display device according to some embodiments of the present disclosure.

Some exemplary embodiments of the present disclosure further provide a display device 2000. Referring to FIG. 14, the display device 2000 includes any display panel 1000 as described above.

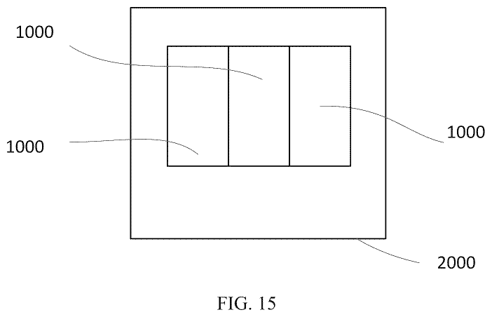

FIG. 15 shows a schematic structural diagram of a display device according to some embodiments of the present disclosure.

For example, in some embodiments of the present disclosure, referring to FIG. 15, a display device 2000 may include a plurality of display panels 1000, and the plurality of display panels may be spliced to achieve a splicing display. In the spliced display panels, the design of wire at the wire outlet end may also adopt the design of wire at the wire outlet end in any display panel 1000 described above, so as to reduce the probability of short circuit at the wire outlet end and improve the yield of the overall display device.

Those skilled in the art may understand that various embodiments of the present disclosure and/or the features described in the claims may be combined in various ways, even if such combinations are not explicitly described in the present disclosure. In particular, without departing from the spirit and teachings of the present disclosure, the various embodiments of the present disclosure and/or the features described in the claims may be combined in various ways. All these combinations fall within the scope of the present disclosure.

The present disclosure has been illustrated and described with reference to specific exemplary embodiments of the present disclosure. However, those skilled in the art should understand that various changes in form and detail may be made to the present disclosure without departing from the spirit and scope of the present disclosure as defined by the appended claims and their equivalents. Therefore, the scope of the present disclosure should not be limited to the above-mentioned embodiments, but should be determined by the appended claims and their equivalents.

1. A display panel, comprising:
a base substrate, comprising a display region and at least one side region, wherein the at least one side region is closer to a side edge of the base substrate than the display region, the at least one side region comprises a first side sub-region and a second side sub-region, and the first side sub-region is closer to the side edge of the base substrate than the second side sub-region;
a plurality of pixel units in the display region, wherein the plurality of pixel units are arranged on the base substrate in an array in a first direction and a second direction intersecting with the first direction, and at least one of the plurality of pixel units comprises a light emitting diode and a pixel driving circuit for driving the light emitting diode;
a plurality of terminals on the base substrate and in the first side sub-region; and
at least one signal wire on the base substrate, wherein at least part of the at least one signal wire extends from the first side sub-region to the display region through the second side sub-region, and the at least one signal wire has one end electrically connected to at least one of the plurality of terminals and the other end electrically connected to the pixel driving circuit;
wherein the display panel further comprises:
a first conductive layer on the base substrate;
a second conductive layer on a side of the first conductive layer away from the base substrate; and
a third conductive layer on a side of the second conductive layer away from the base substrate,
wherein the at least one signal wire comprises a first signal sub-wire, a second signal sub-wire and a third signal sub-wire electrically connected to each other;
the first signal sub-wire is located in the first conductive layer and extends in the first direction;
the second signal sub-wire is located in the second conductive layer and extends in the second direction;
the third signal sub-wire is located in the third conductive layer and extends in the second direction;
at least one of an orthotropic projection of the second signal sub-wire on the base substrate and an orthographic projection of the third signal sub-wire on the base substrate overlaps at least partially with an orthotropic projection of the first signal sub-wire on the base substrate; and
an end of the third signal sub-wire is connected to at least one of the plurality of terminals, the orthographic projection of the second signal sub-wire on the base substrate is closer to the display region than an orthographic projection of the end of the third signal sub-wire connected to the at least one of the plurality of terminals on the base substrate, and the orthographic projection of the second signal sub-wire on the base substrate is spaced apart from an orthographic projection of the at least one of the plurality of terminals on the base substrate in the second direction.

2. The display panel according to claim 1, wherein a part of the orthographic projection of the third signal sub-wire on the base substrate falls within the first side sub-region; and
wherein the second signal sub-wire is electrically connected to the third signal sub-wire through the first signal sub-wire.

3. The display panel according to claim 1, wherein the second signal sub-wire is electrically connected to the first signal sub-wire through at least one first via hole.

4. The display panel according to claim 3, wherein the display panel further comprises a conductive transfer portion in the second conductive layer; and
wherein the third signal sub-wire is electrically connected to a first end of the conductive transfer portion through a second via hole.

5. The display panel according to claim 4, wherein a second end of the conductive transfer portion is electrically connected to the first signal sub-wire through a third via hole.

6. The display panel according to claim 1, wherein the display panel further comprises m data lines and n signal wires, the plurality of terminals comprise m data terminals and n signal terminals, the m data lines have m ends electrically connected to the m data terminals respectively, and the n signal wires have n ends electrically connected to the n signal terminals respectively, wherein m and n are positive integers greater than or equal to 3; and
wherein at least one of the m data terminals is provided between any two adjacent signal terminals among the n signal terminals.

7. The display panel according to claim 6, wherein the m data lines are located in the second conductive layer; and
wherein at least one of the m data lines is provided between second signal sub-wires of any two adjacent signal wires among the n signal wires in the second conductive layer.

8. The display panel according to claim 1, wherein at least one of the plurality of terminals comprises a first sub-terminal in the second conductive layer and a second sub-terminal in the third conductive layer, and the first sub-terminal is electrically connected to the second sub-terminal through a fourth via hole.

9. The display panel according to claim 8, wherein in the second conductive layer, the second signal sub-wire comprises a cut-off side facing the first sub-terminal, the first sub-terminal comprises a first surface facing the cut-off side, and the cut-off side is spaced apart from the first surface by a predetermined distance in the second direction.

10. The display panel according to claim 9, wherein in the second direction, the cut-off side of the second signal sub-wire is closer to the at least one of the plurality of terminals than the first signal sub-wire electrically connected to the second signal sub-wire.

11. The display panel according to claim 10, wherein in the second direction, the cut-off side of the second signal sub-wire is closer to the at least one of the plurality of terminals than each of a first via hole electrically connected to the second signal sub-wire, a second via hole electrically connected to the second signal sub-wire, and a third via hole electrically connected to the second signal sub-wire.

12. The display panel according to claim 1, wherein in the second side sub-region, the orthographic projection of the third signal sub-wire on the base substrate covers an orthotropic projection of the second signal sub-wire transmitting a same signal as the third signal sub-wire on the base substrate.

13. The display panel according to claim 12, wherein in the second side sub-region, a width of the orthographic projection of the third signal sub-wire on the base substrate in the first direction is greater than a width of the orthographic projection of the second signal sub-wire transmitting the same signal as the third signal sub-wire on the base substrate in the first direction.

14. The display panel according to claim 6, wherein the n signal wires comprise at least two of:
a first voltage signal wire configured to transmit a first voltage signal;
a second voltage signal wire configured to transmit a second voltage signal;
a third voltage signal wire configured to transmit a third voltage signal;
an initialization signal wire configured to transmit an initialization signal; and
a pulse voltage signal wire configured to transmit a pulse voltage signal;
wherein cut-off sides of the second signal sub-wires of the n signal wires are respectively opposite to and spaced apart from first surfaces of the n signal terminals in the second direction; and
wherein n distances between the cut-off sides of the second signal sub-wires of the n signal wires and the first surfaces of the n signal terminals in the second direction are substantially equal to each other.

15. (canceled)

16. The display panel according to claim 6, wherein:
in the second conductive layer, a data line is provided between second signal sub-wires of any two adjacent signal wires among the n signal wires; or
in the second conductive layer, two or more data lines are provided between second signal sub-wires of any two adjacent signal wires among the n signal wires; or
in the second conductive layer, a data line is provided between second signal sub-wires of two adjacent signal wires among at least two of the n signal wires, and two or more data lines are provided between second signal sub-wires of two adjacent signal wires among remaining ones of the n signal wires,
wherein the first signal sub-wires of the n signal wires comprise at least two of:
first signal sub-wire of a first voltage signal wire configured to transmit a first voltage signal;
a first signal sub-wire of a second voltage signal wire configured to transmit a second voltage signal;
a first signal sub-wire of a third voltage signal wire configured to transmit a third voltage signal;
a first signal sub-wire of an initialization signal wire configured to transmit an initialization signal; and
a first signal sub-wire of a pulse voltage signal wire configured to transmit a pulse voltage signal,
wherein in the second side sub-region, the first signal sub-wires of at least two of the n signal wires are arranged at intervals in the second direction; and
wherein in the second side sub-region, the first signal sub-wire of the pulse voltage signal wire, the first signal sub-wire of the third voltage signal wire, the first signal sub-wire of the second voltage signal wire, the first signal sub-wire of the first voltage signal wire and the first signal sub-wire of the initialization signal wire are arranged at intervals and sequentially arranged away from the plurality of terminals in the second direction.

17-18. (canceled)

19. The display panel according to claim 3, wherein in the second side sub-region, first via holes respectively configured to electrically connect first signal sub-wires and second signal sub-wires of at least two signal wires are spaced apart from each other in the first direction and the second direction.

20. The display panel according to claim 4, wherein in the second side sub-region, second via holes respectively configured to electrically connect third signal sub-wires at least two signal wires and conductive transfer portions are spaced apart from each other in the first direction and aligned with each other in the second direction.

21. The display panel according to claim 1, wherein:
in the second side sub-region, a width of the orthographic projection of the third signal sub-wire on the base substrate in the first direction is greater than a width of an orthographic projection of a second signal sub-wire transmitting a same signal as the third signal sub-wire on the base substrate in the first direction; and/or
in the second side sub-region, the width of the orthographic projection of the second signal sub-wire on the base substrate in the first direction is greater than a width of an orthographic projection of a data line on the base substrate in the first direction.

22. A display device, comprising the display panel of claim 1.

23. The display device according to claim 22, wherein the display device comprises a plurality of display panels spliced together.
